(19) United States
(12) Patent Application Publication
(10) Pub. No.: US 2002/0080655 A1
(43) Pub. Date: Jun. 27, 2002

(54) Integrated circuit having synchronized pipelining and method therefor

(76) Inventors: Lawrence T. Clark, Phoenix, AZ (US); Jay B. Miller, Phoenix, AZ (US)

Correspondence Address: BLAKELY SOKOLOFF TAYLOR & ZAFMAN, 12400 WILSHIRE BOULEVARD, SEVENTH FLOOR, LOS ANGELES, CA, 90025, US

(21) Appl. No.: 09/750,389

(22) Filed: Dec. 27, 2000

(51) Int. Cl. G11C 7/00

(52) U.S. Cl. 365/191; 365/49; 365/233

(57) ABSTRACT

Briefly, in accordance with one embodiment of the invention, a integrated circuit may generate and store a synchronization signal. This synchronization signal may be used as an enable signal to generate other synchronization signals in subsequent cycles of a clock signal.

### BACKGROUND

One technique to improve the efficiency or performance of an integrated circuit (e.g., a microprocessor) is to arrange the integrated circuit as pipelined stages so that the integrated circuit may begin the execution of sequential operations in parallel. Pipelined architectures often involve the use of redundant combinational circuitry that is used to enable the pipeline stages to control when the stages may begin. However, the more nested or complex the pipeline architecture, the more combinational logic may be used to predict or enable the operation of subsequent stages in the pipeline. Thus, the combinational logic associated with the stages may increase the overall size, complexity, and power consumption of the integrated circuit.

Thus, there is a continuing need for better ways to execute instructions in pipelined processors that are less complicated and that consume less power

### BRIEF DESCRIPTION OF THE DRAWINGS

The subject matter regarded as the invention is particularly pointed out and distinctly claimed in the concluding portion of the specification. The invention, however, both as to organization and method of operation, together with objects, features, and advantages thereof, may best be understood by reference to the following detailed description when read with the accompanying drawings in which:

FIG. 1 is a schematic representation of a portion of an integrated circuit in accordance with an embodiment of the present invention;

FIG. 2 is a timing diagram in accordance with an embodiment of the present invention; and

FIG. 3 is a schematic representation of an alternative embodiment of the present invention.

It will be appreciated that for simplicity and clarity of illustration, elements illustrated in the figures have not necessarily been drawn to scale. For example, the dimensions of some of the elements are exaggerated relative to other elements for clarity. Further, where considered appropriate, reference numerals have been repeated among the figures to indicate corresponding or analogous elements.

### DETAILED DESCRIPTION

In the following detailed description, numerous specific details are set forth in order to provide a thorough understanding of the invention. However, it will be understood by those skilled in the art that the present invention may be practiced without these specific details. In other instances, well-known methods, procedures, components and circuits have not been described in detail so as not to obscure the present invention.

Some portions of the detailed description which follows are presented in terms of algorithms and symbolic representations of operations on data bits or binary digital signals within a computer memory. These algorithmic descriptions and representations may be the techniques used by those skilled in the data processing arts to convey the substance of their work to others skilled in the art.

An algorithm is here, and generally, considered to be a self-consistent sequence of acts or operations leading to a desired result. These include physical manipulations of physical quantities. Usually, though not necessarily, these quantities take the form of electrical or magnetic signals capable of being stored, transferred, combined, compared, and otherwise manipulated. It has proven convenient at times, principally for reasons of common usage, to refer to these signals as bits, values, elements, symbols, characters, terms, numbers or the like. It should be understood, however, that all of these and similar terms are to be associated with the appropriate physical quantities and are merely convenient labels applied to these quantities.

In the following description and claims, the terms “coupled” and “connected,” along with their derivatives, may be used. It should be understood that these terms are not intended as synonyms for each other. Rather, in particular embodiments, “connected” may be used to indicate that two or more elements are in direct physical or electrical contact with each other. “Coupled” may mean that two or more elements are in direct physical or electrical contact. However, “coupled” may also mean that two or more elements are not in direct contact with each other, but yet still co-operate or interact with each other.

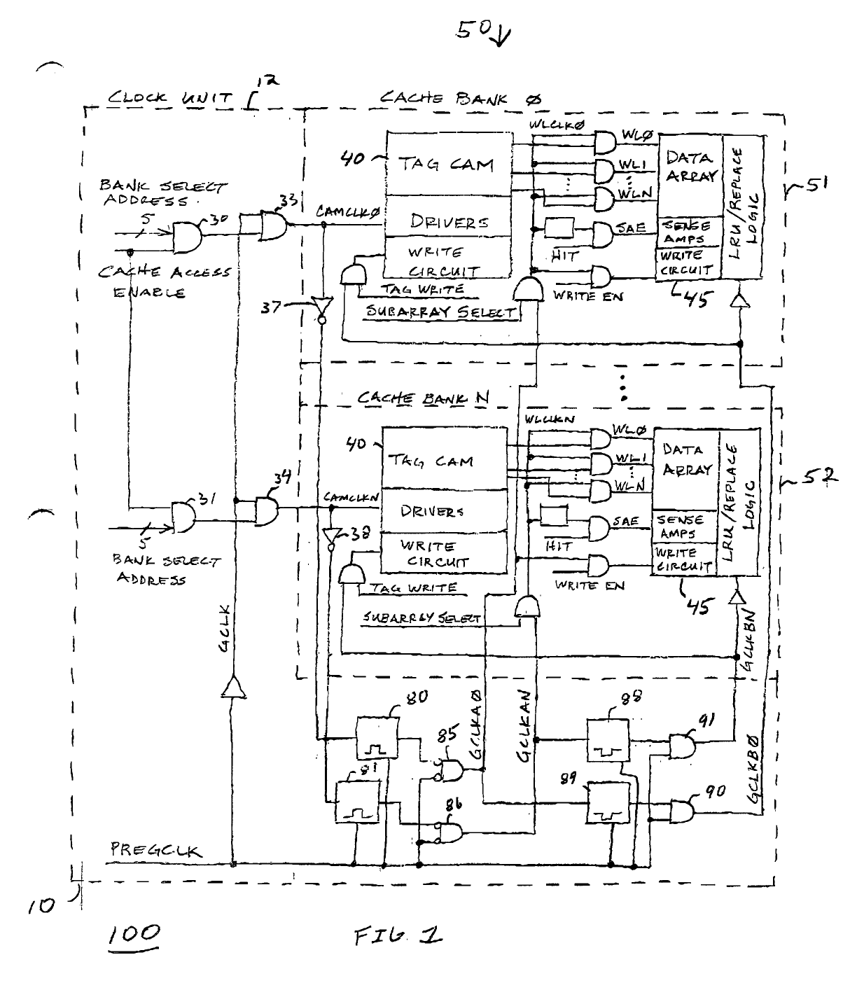

Turning to FIG. 1, an embodiment 100 in accordance with the present invention is described. Embodiment 100 may comprise a portable device such as a mobile communication device (e.g., cell phone), a two-way radio communication system, a one-way pager, a two-way pager, a personal communication system (PCS), a portable computer, or the like. Although it should be understood that the scope and application of the present invention is in no way limited to these examples.

Embodiment 100 here includes an integrated circuit 10 that may comprise, for example, a microprocessor, a digital signal processor, a microcontroller, or the like. However, it should be understood that only a portion of integrated circuit 10 is included in FIG. 1 and that the scope of the present invention is not limited to these examples. Integrated circuit may be coupled to other integrated circuits or components (not shown) such as static random access memory, etc. as part of a larger system.

Integrated circuit 10 may comprise a clock unit 12 that may be to enable or control the operation of a cache 50. However, as will be explained in more detail below, the scope of the present invention is in no way limited to the operation of a cache and alternative embodiments will become apparent to those skilled in the art. In this particular embodiment, cache 50 may be divided into two or more cache banks (e.g., cache banks 51-52). Although only two cache banks 51-52 are shown, it should be understood that portions of the circuits or devices shown in FIG. 1 may be repeated to from addition banks as indicated with the repeating dots.

Cache banks 51-52 may comprise a tag array 40 that may be used to store portions of address corresponding to the data stored in a data array 45. As shown in FIG. 1, tag arrays 40 may comprise tag content addressable memory (CAMs), and drivers and write circuitry to write data into tag array 40. Data arrays 45 may comprise a data array to store the data corresponding the to the appropriate address in the tag CAM of tag array 40. Data array 45 may also comprise sense amps use to read the data, as well as write circuitry and least recently used (LRU) circuitry to store data within data array 45. It should be understood that the scope of the present invention is not limited to the embodiment shown in FIG. 1 as other cache arrangement may be used in alternative embodiments of the invention.

During the operation of integrated circuit 10, a request may be made for data. For example, integrated circuit 10 may be a processor, and the request may represent a request for the next instruction to be executed or for data associated with an operand of an instruction. This request may begin by providing the address of the information desired along with assertion of a Cache Access Enable signal to permit accesses to cache 50. As shown in FIG. 1, combinational logic (e.g., AND gates 30-31 may be used to determine which of cache banks 51-52 corresponds to the address. Assuming for purposes of illustration that the address corresponds to cache bank 51, AND gate 30 will generate an enable signal indicating that at least a portion of the address of the requested data (e.g., at least five bits) corresponds to cache bank 51. Likewise, AND gate 31 will not assert an enable signal to indicate that requested data is not in cache bank 52.

Combinational logic (e.g., AND gates 33-34 in this embodiment) may used to generate a synchronization signal for the corresponding cache banks 51-52. AND gate 33 may generate a signal, labeled CAMCLOCK0, that roughly approximates the period and cycle of a clock signal (e.g., a global or system clock signal labeled GCLK). One skilled in art will recognize that the CAMCLOCK0 signal and GCLK signal may not exactly be the same due to the delay associated with the combinational logic (e.g., AND gate 33).

One skilled in the art should appreciate that CAMCLOCK0 signal is a conditional, synchronization signal. Although the scope of the present invention is not limited in this respect, CAMCLK0 is conditional in the sense that it has been encoded with information indicating that at least a portion of the address of the requested data is a match and that a cache access is permitted. In this embodiment, CAMCLK0 may also be used as a synchronization signal in the sense that it may have a regular period or cycle that roughly approximates the period or cycle of the clock signal, GCLK. Hence, CAMCLK0 may be used to enable and control the operation of tag array 40 to perform a tag lookup and determine if the address of the requested data corresponds to one of the addresses in tag array 40.

As indicated in FIG. 1, CAMCLK0 and CAMCLKN signals may pass through optional inverters 37-38 and be stored in latches 80-81. Although the scope of the present invention is not limited in this respect, synchronization signals CAMCLK0-N may be stored in latches 80-81 at the end of a cycle or period change of a system or control clock signal, labeled PREGCLK. Since synchronization signals CAMCLK0-N are delayed due to combinational logic between PREGCLK and the output of AND gates 33-34, the CAMCLCKO-N may be valid longer, and hence, PREGCLK may be used to trigger storing CAMCLK0-N in latches 80-81.

It should be understood that the scope of the present invention is not limited to the use of latches to store synchronization signals CAMCLK0-N or by the particular type of latch used to store the signals. In alternative embodiments, other latches or storage devices (e.g., combinational logic arranged in a feedback loop, etc.) may be used. In this particular embodiment, latches 80-81 may store at least a portion of the synchronization signal generated during a previous cycle of a clock signal (e.g., PREGCLK). Because this signal has been stored, it may be used to generate future conditional synchronization signals that may be used to enable or control the operation of subsequent stages of integrated circuit 10.

In this particular embodiment, the synchronization signals CAMCLK0-N may be used to generate a synchronization signal that may be use to control the operation of data arrays 45. For example, latches 80-81 may provide previously generated synchronization signals to combinational logic (e.g., NOR gates 85-86), which, in turn, may generate another synchronization signal. NOR gates 85-86 may use the information stored in latches 85-86 as an enable signal to generate a synchronization signal, labeled GCLKA0-N, that roughly approximates the cycle or period of PREGCLK.

In this particular example, latch 80 will have an asserted value (a logic ‘O’ due to inverter 37) indicating that requested data may be in cache bank 51. Likewise, latch 81 will not contain an asserted value because synchronization signal CAMCLKN was not asserted since the address of the requested data did not correspond to cache bank 52. Consequently, only NOR gate 85 may generate a synchronization signal (e.g., GCLKA0). Although the scope of the present invention is not limited in this respect, it should be noted that the synchronization signal, GCLKA0, may be generated during a cycle of the clock signal, PREGCLK, that is a cycle after when the synchronization signal CAMCLK0 was generated.

The synchronization signal GCLKA0 may be used by combinational logic in cache bank 51 to enable and control the operation of data array 45. For example, the synchronization signal may be used to enable word lines, sense amps, and the appropriate write or read circuitry within cache 50. Thus, GCLKA0 may be used to synchronize or execute a cache access (e.g., a read or write of data array 45).

However, since NOR gate 86 did not generate the synchronization signal GCLKAN, the sense amps, word lines, and read/write circuitry associated with cache bank 51 will not be enabled, which may save power. It should be noted that since there are likely to be more than just two cache banks (e.g., cache banks 51-52) the amount of power savings may be proportional to the number of cache banks that are not enabled.

Continuing with this example, at least a portion of synchronization signals GCLKA0-N may be stored in latches 88-89. Although the scope of the present invention is not limited in this respect, PREGCLK may be used to store the value generated by NOR gates 85-86. Since NOR gates 85-86 may generate a synchronization signal that roughly approximates a delayed version of PREGCLK, the value of synchronization signals GCLKA0-N may be stored in latches at the end of a cycle of the PREGCLK clock signal. Since the value of the synchronization signals, GCLKA0-N, is stored, they may be used as enable signals in the generation of subsequent synchronization signals to control or enable the operation of other portions of integrated circuit 10.

For example, combinational logic (e.g., AND gates 90-91) may be used to generate a synchronization signal to control the updating of the LRU/replace logic of cache banks 50-51. In this example, latch 89 may store an asserted value indicating that GCLKA0 was generated in a previous clock signal. Likewise, latch 88 may store a de-asserted value since NOR gate 86 did not generate a synchronization signal (e.g., because the synchronization signal CAMCLKN was not asserted in the previous cycles of PREGCLK). Thus, in this example, only AND gate 90 generates a synchronization to enable or control the updating of cache bank 51.

Although the scope of the present invention is not limited in this respect, the synchronization signal, GCLKBO, generated by AND gate 90 roughly approximates the cycle or period of PREGCLK and may be offset by the delay associated with the combinational logic (AND gate 90 in this example).

Because the synchronization signals CAMCLKN or GCLKAN were not generated during a previous cycle of the clock signal (e.g., PREGCLK), latch 88 may store a de-asserted value that may disable AND gate 91 from generating a synchronization signal. Since synchronization signal CAMCLKBN is not generated, the power associated with the operation of the LRU/replace logic for cache bank 51 may be saved.

As demonstrated from this example, the synchronization signal used to control or enable the operation of one stage of a pipeline or state machine (e.g., one of tag arrays 40) is used to conditionally generate another synchronization signal that may be used to control or enable another portion of integrated circuit 10 (e.g., one of data arrays 45). Although the scope of the present invention is not limited in this respect, a clock signal (e.g. PREGCLK) may be used to control when synchronization signals are created or stored.

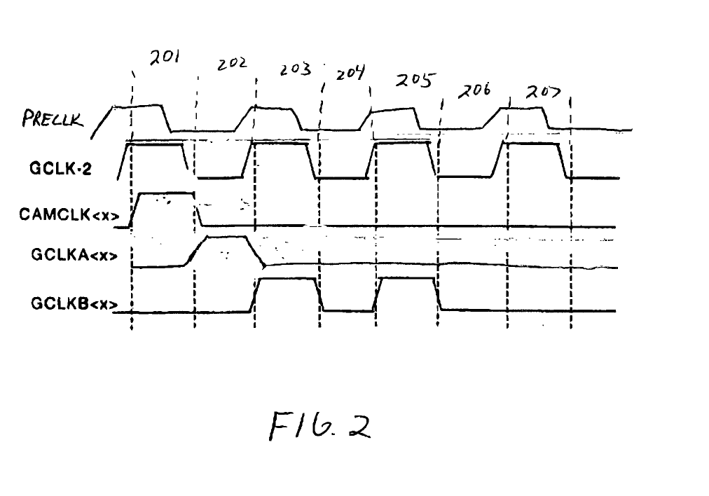

FIG. 2 is a timing diagram of the example described above and is provided to further demonstrate the relationship between various synchronization signals. In this particular example, the synchronization signals may generated during a cycle of a clock signal (e.g. PREGCLK). As shown in FIG. 2, PREGCLK has seven cycles 201-207. Although the scope of the present invention is not limited in this respect, a cycle is defined as the amount of time that the clock signal is in a high or low state (e.g. a cycle of a state machine begins with a rising edge of a clock signal and ends with a subsequent falling edge of a clock signal, or begins with a falling edge of a clock signal and ends with a subsequent rising edge of a clock signal).

Such a nomenclature may be desirable if integrated circuit 10 is a pipeline processor or state machine that executes operations during each phase change of a clock. However, it should also be understood that alternative embodiments of the present invention may also store or generate synchronization signals during the an entire cycle of a clock signal. For example, the time from when PREGCLK is a high value, transitions to a low value, and then transitions back to a high value (e.g. the time between repetitious rising edges). Although the scope of the present invention is not limited in this respect, integrated circuit 10 may be arranged such that each phase change or cycle of a system clock may represent an execution or operation cycle during which all or part of an instruction may be performed.

As indicated in FIG. 2, GCLK closely approximates PREGCLK, but is delayed to combinational logic. In this case, the synchronization signal (e.g., CAMCLK0) may be generated during the first cycle 201. Since CAMCLK0 is generated by combinational logic, it closely approximates (e.g., may be substantially equal to) GCLK although slightly delayed due to AND gate 35. Because the CAMCLK0 signal remain high slightly longer than PREGCLK, the falling edge of PREGCLK may be used to latch or store the value of CAMCLK0 in latch 80 and the end of cycle 201. Thus, the CAMCLK0 signal is generated and stored in one clock cycle (e.g. a phase change of PREGCLK).

During the next cycle 202, the value stored in latch 80 may be used to enable NOR gate 85 to generate the synchronization signal GCLKA0 (e.g. a prior synchronization signal may be combined with a clock to generate another synchronization signal). Thus, integrated circuit is adapted to generate a synchronization signal in cycle 202 based in part on the presence of another synchronization signal in a previous cycle; in this example, the prior cycle (e.g. cycle 201).

As discussed above, the synchronization signal GCLKA0 may be stored by latched 89 to be used to generate yet another synchronization signal in a subsequent clock cycle. In this case, AND gate 90 may be enabled by the presence of GCLKA0 and generate synchronization signal GCLKBO during cycle 203 of the clock signal, PREGCLK. As shown in FIG. 2, GCLKBO is substantially equal or is synchronized to GCLK and PREGCLK.

Although the examples referred to with respect to FIGS. 1-2 were related to accessing data in a cache, the scope of the present invention is not limited in this respect. In alternative embodiments, the use of previous synchronization signals to generate subsequent synchronization signals may be used for a variety of applications. For example, this technique may be used to synchronize instructions in a pipelined processor or a state machine.

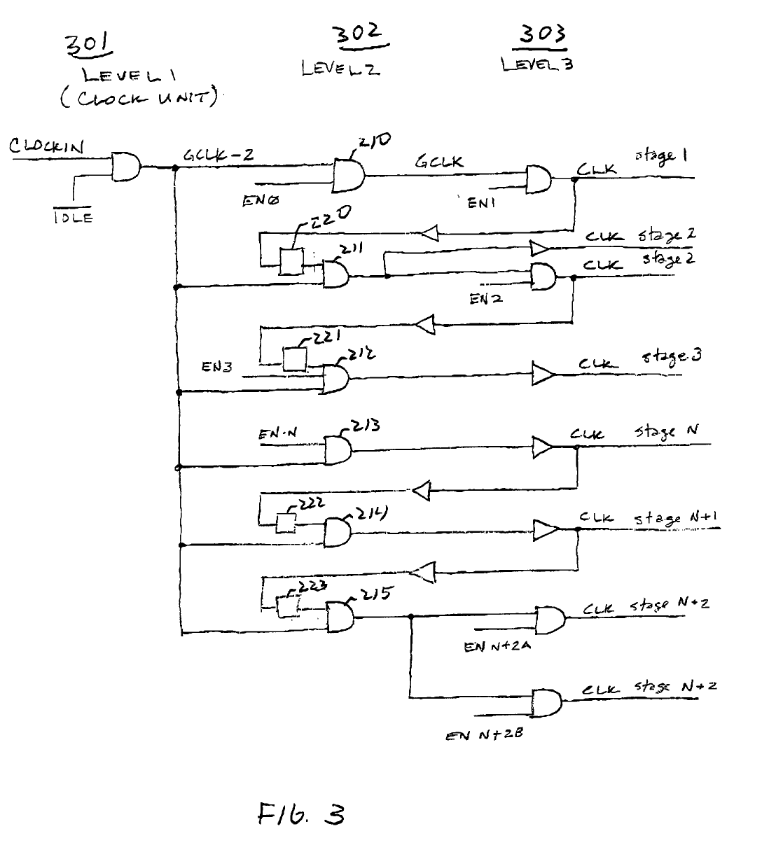

FIG. 3 is provided to demonstrate how the present invention may be abstracted so that it might apply in a variety of applications. FIG. 3 illustrates schematically an alternative of the present invention that three levels of clock or synchronization signal generation regions 301-303. However, it should be understood that the scope of the present invention is not limited in this respect as one skilled in the art will appreciate how the present invention may be extended to provide as many levels of clock generation as desired.

In a first level (e.g., region 301) a master clock, labeled CLOCKIN, is gated with an enable signal (e.g., Idle) and generates a clock signal, GCLK-2 when the integrated circuit is not in an idle mode. The synchronization signal (e.g., GCLK-2) may be combined with enable signals (e.g., EN0, EN3, or EN4) and combination logic (e.g., AND gates 210-215) to generate the next level of synchronization signals (region 302). These synchronization signals may be further gated with other enable signals or combinational logic to provide yet a further level of nested synchronization signals (region 303). Alternatively, the synchronization signals may be stored in latches 220-223 so that they may be used to enable the generation of other synchronization signals that are synchronized to GCLK-2. By using previous synchronization signals as enable signals for the creation of other synchronization signals, particular embodiments of the present invention may be able to take advantage of the encoded information already contained within the previous synchronization signals. This may reduce the number of subsequent synchronization signals that may be generated, which in turn, may reduce the amount of power consumed by the integrated circuit.

While certain features of the invention have been illustrated and described herein, many modifications, substitutions, changes, and equivalents will now occur to those skilled in the art. It is, therefore, to be understood that the appended claims are intended to cover all such modifications and changes as fall within the true spirit of the invention.

1. A method comprising:
generating a first conditional synchronization signal during a first cycle of a state machine; and
generating a second conditional synchronization signal using the first conditional synchronization signal, wherein the second conditional synchronization signal is generated during a second cycle of the state machine.

2. The method of claim 1, wherein generating the first conditional synchronization signal includes generating the first conditional synchronization signal during a cycle provided by a system clock.

3. The method of claim 1, wherein generating the second conditional synchronization signal includes combining the first conditional synchronization signal with a clock signal.

4. The method of claim 1, wherein generating the second conditional synchronization signal includes combining the first conditional synchronization signal with an enable signal.

5. The method of claim 1, wherein generating the first conditional synchronization signal includes generating the first conditional synchronization signal during a first cycle of a state machine defined by a repetition of a rising edge of a system clock.

6. The method of claim 1, wherein generating the first conditional synchronization signal includes generating the first conditional synchronization signal during a first cycle of a state machine that begins with a rising edge of a clock signal and that ends with a subsequent falling edge of a clock signal.

7. The method of claim 1, wherein generating the first conditional synchronization signal includes generating the first conditional synchronization signal during a first cycle of a state machine that begins with a falling edge of a clock signal and that ends with a subsequent rising edge of a clock signal.

8. The method of claim 1, wherein generating the second conditional synchronization signal occurs during a second cycle of the state machine that immediately follows the first cycle of the state machine.

9. The method of claim 1, further comprising capturing the first conditional synchronization signal.

10. The method of claim 9, wherein capturing the first conditional synchronization signal includes latching at least a portion of the first conditional synchronization signal in a latch.

11. The method of claim 10, wherein latching at least a portion of the first conditional synchronization signal includes latching at least a portion of the first conditional synchronization signal in response to a transition in a clock signal.

12. The method of claim 1, further comprising executing a cache tag lookup during the first cycle of the state machine.

13. The method of claim 12, further comprising executing a cache data access during the second cycle of the state machine.

14. The method of claim 1, wherein generating the first conditional synchronization signal includes generating the first conditional synchronization signal during a first cycle of a state machine that begins with a first transition of a clock signal and ends with a second transition of the clock signal.

15. The method of claim 1, further comprising generating a third conditional synchronization signal using the second conditional synchronization signal during a third cycle of the state machine.

16. The method of claim 1, wherein generating a second conditional synchronization signal includes generating a second conditional synchronization signal that is substantially synchronized with a system clock signal.

17. The method of claim 16, wherein generating a first conditional synchronization signal includes generating a first conditional synchronization signal that is substantially synchronized with the system clock signal.

18. The method of claim 16, wherein generating a second conditional synchronization signal includes generating a second condition synchronization signal one cycle of a system clock signal later than the first conditional synchronization signal.

19. A method comprising:
generating a first synchronization signal during a cycle of a clock signal;
providing the first synchronization signal to combinational logic; and
generating a second synchronization signal with the combinational logic during a subsequent clock cycle.

20. The method of claim 19, wherein generating the first and second synchronization signal includes generating a first and a second synchronization signal that are substantially synchronized to the clock signal.

21. The method of claim 19, further comprising storing at least a portion of the first synchronization signal.

22. The method of claim 21, wherein storing at least a portion of the first synchronization signal includes at least a portion of the first synchronization signal in a latch.

23. The method of claim 19, wherein generating a second synchronization signal includes generating a second synchronization only if an enable signal is provided.

24. The method of claim 19, further comprising:
enabling a cache tag lookup with the first synchronization signal; and
enabling a cache data access with the second synchronization signal.

25. The method of claim 19, wherein generating the second synchronization signal occurs during the subsequent clock signal only if the first synchronization signal was generated during a previous clock cycle.

26. The method of claim 19, wherein generating the second synchronization signal includes enabling the transmission of the clock signal with the first synchronization signal.

27. An integrated circuit comprising:
a first portion adapted to generate a first synchronization signal during a execution stage; and
a second portion adapted to receive the first synchronization signal and generate a second synchronization signal during a subsequent execution stage.

28. The integrated circuit of claim 27, further comprising a cache having a tag lookup array, wherein the tag lookup array is enabled, at least in part, by the first synchronization signal.

29. The integrated circuit of claim 27, further comprising a cache having a data array, wherein the data array is enabled, at least in part, by the second synchronization signal.

30. The integrated circuit of claim 27, further comprising a storage unit adapted to store at least a portion of the first synchronization signal.

31. The integrated circuit of claim 30, wherein the storage unit is further adapted to provide the first synchronization signal to the second portion.

32. The integrated circuit of claim 30, wherein the storage unit comprises a latch.

33. The integrated circuit of claim 27, wherein the second portion is adapted to receive a clock signal, and the second portion is adapted to generate a second synchronization signal that is substantially equal to the clock signal.

34. The integrated circuit of claim 27, wherein the second portion is adapted to receive an enable signal and generate the second synchronization signal if the enable signal and the first synchronization signal are present.

35. An apparatus comprising:
a static random access memory; and
a processor coupled to the static random access memory, wherein the processor includes:
a first portion adapted to generate a first synchronization signal during a execution stage; and
a second portion adapted to receive the first synchronization signal and generate a second synchronization signal during a subsequent execution stage.

36. The apparatus of claim 35, wherein the processor further comprises a cache having a tag lookup array, wherein the tag lookup array is enabled, at least in part, by the first synchronization signal.

37. The apparatus of claim 35, wherein the processor further comprises a cache having a data array wherein the data array is enabled, at least in part, by the second synchronization signal.

38. The apparatus of claim 35, wherein the processor further comprises a latch adapted to store at least a portion of the first synchronization signal.
